(19) United States
(12) Patent Application Publication
(10) Pub. No.: US 2012/0132261 A1
(43) Pub. Date: May 31, 2012

(54) CADMIUM STANNATE SPUTTER

(76) Inventors: Benyamin Buller, Perrysburg, OH (US); Douglas Dauson, Perrysburg, OH (US); Scott Mills, Perrysburg, OH (US); Dale Roberts, Temperance, MI (US); Yu Yang, Perrysburg, OH (US); Zhibo Zhao, Novi, MI (US); Keith Burrows, Mineral Point, WI (US); Klaus Hartig, Avoca, WI (US); Annette Krisko, Spring Green, WI (US)

(21) Appl. No.: 13/171,987

(22) Filed: Jun. 29, 2011

Related U.S. Application Data
(60) Provisional application No. 61/360,216, filed on Jun. 30, 2010.

(51) Int. Cl. H01L 31/048; H01L 31/0224

(52) U.S. Cl. 136/251; 136/256

(57) ABSTRACT

A structure includes a barrier layer which can include a silicon aluminum oxide, and a transparent conductive oxide layer which can include a layer of cadmium and tin.

### CLAIM FOR PRIORITY

This application claims priority under 35 U.S.C. §119(e) to Provisional U.S. Patent Application Ser. No. 61/360,216, filed on Jun. 30, 2010, which is hereby incorporated by reference.

### TECHNICAL FIELD

The present invention relates to photovoltaic devices and methods of production.

### BACKGROUND

Photovoltaic devices can include semiconductor material deposited over a substrate, for example, with a first layer serving as a window layer and a second layer serving as an absorber layer. The semiconductor window layer can allow the penetration of solar radiation to the absorber layer, such as a cadmium telluride layer, which converts solar energy to electricity. Photovoltaic devices have not been highly efficient.

### DESCRIPTION OF DRAWINGS

FIG. 1 is a schematic of a multilayered substrate.

FIG. 2 is a schematic of a photovoltaic device having multiple layers.

FIG. 3 is a schematic of a sputter deposition chamber.

### DETAILED DESCRIPTION

Photovoltaic devices can include multiple layers created on a substrate (or superstrate). For example, a photovoltaic device can include a barrier layer, a transparent conductive oxide (TCO) layer, a buffer layer, and a semiconductor layer formed in a stack on a substrate. Each layer may in turn include more than one layer or film. For example, the semiconductor layer can include a first film including a semiconductor window layer formed on the buffer layer and a second film including a semiconductor absorber layer formed on the semiconductor window layer. Additionally, each layer can cover all or a portion of the device and/or all or a portion of the layer or substrate underlying the layer. For example, a “layer” can include any amount of any material that contacts all or a portion of a surface.

In one aspect, a sputter target may include a sputter material including cadmium and tin. The sputter material may include about 60 to about 75 wt. % cadmium. The sputter material may include about 65 to about 68 wt. % cadmium. The sputter target may include a stainless steel tube. The sputter material may be connected to the stainless steel tube to form a sputter target. The sputter material may include a bonding layer bonding the sputter material and the backing tube. The sputter target may be configured to use in a reactive sputtering process. The sputter target can include nickel, zinc, indium, lead, or bismuth. The sputter target can include more than about 0.001 wt. % nickel. The sputter target can include less than about 1.0 wt. % nickel. The sputter target can include about 0.001 to about 1.0 wt. % nickel. The sputter target can include about 0.005 to about 0.5 wt. % nickel. The sputter target can include about 0.01 to about 0.1 wt. % nickel.

In one aspect, a method of manufacturing a rotary sputter target may include forming a sputter material including cadmium and tin. The sputter material may include about 60 to about 75 wt. % cadmium. The method may include attaching the sputter material to a backing tube to form a sputter target. The step of attaching the sputter material to a backing tube to form a sputter target may include a thermal spray forming process. The step of attaching the sputter material to a backing tube to form a sputter target may include a plasma spray forming process. The step of attaching the sputter material to a backing tube to form a sputter target may include a powder metallurgy process. The powder metallurgy process may include a hot press process. The powder metallurgy process may include an isostatic process. The step of attaching the sputter material to a backing tube to form a sputter target may include a flow forming process. The step of attaching the sputter material to the backing tube may include bonding the sputtering material to the backing tube with a bonding layer.

In one aspect, a multilayered structure can include a substrate, a barrier layer comprising silicon aluminum oxide adjacent to the substrate, a transparent conductive oxide layer comprising cadmium stannate adjacent to the barrier layer, and a buffer layer comprising tin oxide adjacent to the transparent conductive oxide layer.

The transparent conductive oxide layer can include a material selected from the group consisting of nickel, zinc, indium, lead, and bismuth. The structure can include more than about 0.001 wt. % nickel. The structure can include less than about 1.0 wt. % nickel. The structure can include about 0.001 to about 1.0 wt. % nickel. The structure can include about 0.005 to about 0.5 wt. % nickel. The structure can include about 0.01 to about 0.1 wt. % nickel. The transparent conductive oxide layer can have a sheet resistance of more than about 100 Ohms/square. The transparent conductive oxide layer can have a sheet resistance of less than about 1500 Ohms/square. The transparent conductive oxide layer can have a sheet resistance of about 200 to about 1000 Ohms/square. The transparent conductive oxide layer can have a sheet resistance of about 800 to about 1200 Ohms/square. The transparent conductive oxide layer can have a sheet resistance of about 100 to about 500 Ohms/square. The transparent conductive oxide layer may include an annealed layer having a sheet resistance of more than about 5 Ohms/square. The transparent conductive oxide layer may include an annealed layer having a sheet resistance of less than about 15 Ohms/square.

In one aspect, a photovoltaic can include a substrate, a barrier layer comprising silicon aluminum oxide adjacent to the substrate, a transparent conductive oxide layer comprising cadmium stannate adjacent to the barrier layer, and a buffer layer comprising tin oxide adjacent to the transparent conductive oxide layer. The photovoltaic device can include a semiconductor window layer adjacent to the buffer layer, a semiconductor absorber layer adjacent to the semiconductor window layer, and a back contact adjacent to the semiconductor absorber layer. The semiconductor window layer can include cadmium sulfide. The semiconductor absorber layer can include cadmium telluride. The photovoltaic device can include a back support adjacent to the back contact.

The transparent conductive oxide layer can include a material selected from the group consisting of nickel, zinc, indium, lead, and bismuth. The photovoltaic device can include more than about 0.001 wt. % nickel. The photovoltaic device can include less than about 1.0 wt. % nickel. The photovoltaic device can include about 0.001 to about 1.0 wt. % nickel. The structure can include about 0.005 to about 0.5 wt. % nickel. The photovoltaic device can include about 0.01 to about 0.1 wt. % nickel. The transparent conductive oxide layer can have a sheet resistance of more than about 100 Ohms/square. The transparent conductive oxide layer can have a sheet resistance of less than about 1500 Ohms/square. The transparent conductive oxide layer can have a sheet resistance of about 200 to about 1000 Ohms/square. The transparent conductive oxide layer can have a sheet resistance of about 800 to about 1200 Ohms/square. The transparent conductive oxide layer can have a sheet resistance of about 100 to about 500 Ohms/square. The transparent conductive oxide layer may include an annealed layer having a sheet resistance of more than about 5 Ohms/square. The transparent conductive oxide layer may include an annealed layer having a sheet resistance of less than about 15 Ohms/square.

In one aspect, a photovoltaic module may include a plurality of photovoltaic cells adjacent to a substrate. The photovoltaic module may include a back cover adjacent to the plurality of photovoltaic cells. Each one of the plurality of photovoltaic cells may include a barrier layer including silicon aluminum oxide adjacent to the substrate. The photovoltaic cell may include a transparent conductive oxide layer including cadmium stannate adjacent to the barrier layer. The photovoltaic cell may include a buffer layer including tin oxide adjacent to the transparent conductive oxide layer. The photovoltaic cell may include a semiconductor window layer adjacent to the buffer layer. The photovoltaic cell may include a semiconductor absorber layer adjacent to the semiconductor window layer. The photovoltaic cell may include a back contact adjacent to the semiconductor absorber layer.

The photovoltaic module may include a first strip of tape having a length distributed along the back contacts. The first strip of tape may include a front surface and a back surface, each surface containing an adhesive. The photovoltaic module may include a first lead foil distributed along the length of the first strip of tape. The photovoltaic module may include a second strip of tape, having a length shorter than that of the first strip of tape, distributed along the length and between the ends of the first strip of tape. The second strip of tape may include a front and back surface, each containing an adhesive. The photovoltaic module may include a second lead foil, having a length shorter than that of the second strip of tape, distributed along the length of the second strip of tape. The photovoltaic module may include a plurality of parallel bus bars, positioned adjacent and perpendicular to the first and second strips of tape. Each one of the plurality of parallel bus bars may contact one of the first or second lead foils. The photovoltaic module may include first and second submodules. The first submodule may include 2 or more cells of the plurality of photovoltaic cells connected in series. The second submodule may include another 2 or more cells of the plurality of photovoltaic cells connected in series. The first and second submodules may be connected in parallel through a shared cell.

In one aspect, a method for generating electricity may include illuminating a photovoltaic cell with a beam of light to generate a photocurrent. The method may include collecting the generated photocurrent. The photovoltaic cell may include a substrate. The photovoltaic cell may include a barrier layer including silicon aluminum oxide adjacent to the substrate. The photovoltaic cell may include a transparent conductive oxide layer comprising cadmium stannate adjacent to the barrier layer. The photovoltaic cell may include a buffer layer including tin oxide adjacent to the transparent conductive oxide layer. The photovoltaic cell may include a semiconductor window layer adjacent to the buffer layer. The photovoltaic cell may include a semiconductor absorber layer adjacent to the semiconductor window layer. The photovoltaic cell may include a back contact adjacent to the semiconductor absorber layer. The beam of light may include a wavelength of more than about 400 nm. The beam of light may include a wavelength of less than about 700 nm. The beam of light may include ultraviolet light. The beam of light may include blue light. The beam of light may include white light. The method may include converting the photocurrent from DC to AC.

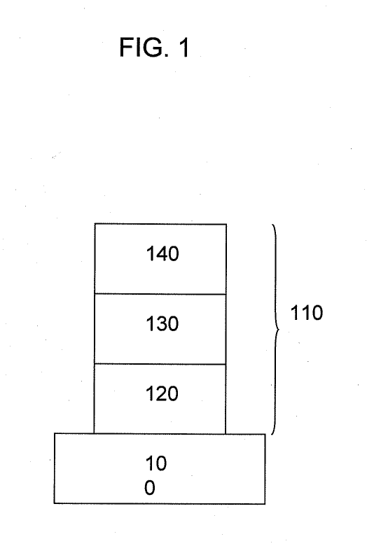

Referring to FIG. 1, by way of example, barrier layer 120 may be deposited onto substrate 100. Substrate 100 may include any suitable material, including, for example, a glass. The glass may include a soda-lime glass, or any glass with reduced iron content. The glass may undergo a treatment step, during which one or more edges of the glass may be substantially rounded. The glass may have any suitable transmittance, including about 450 nm to about 800 nm. The glass may also have any suitable transmission percentage, including, for example, more than about 50%, more than about 60%, more than about 70%, more than about 80%, or more than about 85%. For example, substrate 100 may include a glass with about 90% transmittance.

Barrier layer 120 may be deposited using any suitable means, including, for example, sputtering. Barrier layer 120 may be sputtered from a sputter target including any suitable sputter material, including, for example, a material including a combination of silicon and aluminum. For example, a sputter target for barrier layer 120 may include a sputter material including any suitable ratio of silicon to aluminum. For example, a sputter target for barrier layer 120 may include a sputter material including 5-35 wt. % aluminum. A sputter target for barrier layer 120 may include a sputter material including 15-20 wt. % aluminum. A sputter target for barrier layer 120 may include a backing tube, which may include any suitable material, including, for example, stainless steel. The sputter material may be connected to the backing tube to form the sputter target for barrier layer 120. The sputter target for barrier layer 120 may include a bonding layer for bonding the sputter material to the backing tube. The sputter target for barrier layer 120 may be configured to use in any suitable reactive sputtering process.

Barrier layer 120 may be deposited in the presence of one or more gases, for example, an oxygen gas. An argon gas may be added to the deposition chamber to increase the rate of deposition. For example, barrier layer 120 may include a silicon aluminum oxide sputtered in the presence of an oxygen/argon gas mix. The incorporation of argon into the deposition process can result in a higher deposition rate for barrier layer 120.

Barrier layer 120 may include any suitable material, including, for example, silicon aluminum oxide. Barrier layer 120 can be incorporated between the substrate and the TCO layer to lessen diffusion of sodium or other contaminants from the substrate to the semiconductor layers, which could result in degradation or delamination. Barrier layer 120 can be transparent, thermally stable, with a reduced number of pin holes and having high sodium-blocking capability, and good adhesive properties. Barrier layer 120 can include any suitable number of layers and may have any suitable thickness, including, for example, more than about 500 A, more than about 750 A, or less than about 1200 A. For example, barrier layer 120 may have a thickness of about 1000 A.

A transparent conductive oxide layer 130 can be formed adjacent to barrier layer 120. Transparent conductive oxide layer 130 may be deposited using any suitable means, including, for example, sputtering. Transparent conductive oxide layer 130 may be sputtered from a sputter target including any suitable sputter material, including, for example, a combination of cadmium and tin. For example, a sputter target for transparent conductive oxide layer 130 may include a sputter material including any suitable ratio of cadmium to tin. For example, a sputter target for transparent conductive oxide layer 130 may include a sputter material including more than 60 wt. % cadmium. A sputter target for transparent conductive oxide layer 130 may include a sputter material including less than 75 wt. % cadmium. For example, a sputter target for transparent conductive oxide layer 130 may include a sputter material including 60-75 wt. % cadmium. A sputter target for transparent conductive oxide layer 130 may include a sputter material including 65-68 wt. % cadmium. A sputter target for transparent conductive oxide layer 130 may include a backing tube, which may include any suitable material, including, for example, stainless steel. The sputter material may be connected to the backing tube to form the sputter target for transparent conductive oxide layer 130. The sputter target for transparent conductive oxide layer 130 may include a bonding layer for bonding the sputter material to the backing tube. The sputter target for transparent conductive oxide layer 130 may be configured to use in any suitable reactive sputtering process.

The transparent conductive oxide layer may be part of a TCO stack, which may also include a barrier layer and a buffer layer. The TCO stack layers may be deposited using any suitable technique, including, for example, sputtering. A sputtering target may include any suitable material. A sputter target can be manufactured by ingot metallurgy. A sputter target can be manufactured as a single piece in any suitable shape. A sputter target can be a tube. A sputter target can be manufactured by casting a material into any suitable shape, such as a tube.

A sputter target can be manufactured from more than one piece. For example, if a sputter target includes a cadmium and tin sputter material, the target can be manufactured from more than one piece, such as a piece of cadmium and a piece of tin. The pieces can be manufactured in any suitable shape, such as sleeves, and can be joined or connected in any suitable manner or configuration. For example, a piece of cadmium and a piece of tin can be welded together to form the sputter target. One sleeve can be positioned within another sleeve. A sputter target for a silicon aluminum oxide barrier layer can include a piece of silicon and a piece of aluminum.

A sputter target can be manufactured by powder metallurgy. A sputter target can be formed by consolidating powder (e.g., silicon and aluminum for the barrier target or cadmium and tin for the TCO target) to form the target. The powder can be consolidated in any suitable process (e.g., pressing such as isostatic pressing) and in any suitable shape. The consolidating can occur at any suitable temperature. A sputter target can be formed from powder including more than one material powder (e.g., silicon and aluminum or cadmium and tin). More than one powder can be present in stoichiometrically proper amounts.

Sputter targets (including rotary sputter targets) can include a sputter material used in connection with a backing material. The backing material can include stainless steel. The backing material can include a backing tube. The backing material can include a stainless steel backing tube. The tube can be of any suitable size. For example, the tube can have a length of about 5 to about 15 feet, about 8 to about 12 feet, about 9 to about 11 feet, or about 10 feet. The tube can have a diameter of about 4 to about 12 inches, about 6 to about 8 inches, about 5 to about 7 inches, or about 6 inches. The sputter target for a silicon aluminum oxide barrier layer can include bonding layers applied to the tube surface before application of the silicon:aluminum sputter material.

A sputter target can be manufactured by positioning wire including target material adjacent to a base. For example, wire including target material can be wrapped around a base tube. The wire can include multiple materials (e.g., cadmium and tin for a cadmium stannate TCO layer) present in stoichiometrically proper amounts. The base tube can be formed from a material that will not be sputtered. The wire can be pressed (e.g., by isostatic pressing).

A sputter target can be manufactured by spraying a sputter material onto a base. Sputter material can be sprayed using any suitable spraying process, including thermal spraying and plasma spraying. The sputter material can include multiple materials (e.g., silicon and aluminum for a silicon aluminum oxide barrier layer), present in stoichiometrically proper amounts. The base onto which the target material is sprayed can include a tube.

A sputter target can be manufactured by dissolving an alloy in an acid. The alloy may include any suitable materials, including for example, cadmium and tin. The dissolved metal alloy may then be bonded to the outside of a stainless steel tube. The bond between the tube and the metal alloy can be of a substantially high strength. The sputter targets can be substantially uniform. The sputter target can be manufactured using various suitable techniques, including, for example, casting, which may consist of melting the alloy, pouring it into a mold, and then cooling it quickly. Alternatively, the sputter target may be formed using any suitable powder metallurgy technique, which may include grinding and spraying the precursor materials.

A sputter target can include any suitable ratio of materials. For example, for a sputter target including cadmium and tin, the sputter target can include about 60-75 wt. % cadmium, for example, 65-68 wt. % cadmium. The sputter target can be substantially uniform. The sputter target can be substantially pure, including only trace amounts of various elements, including, for example, zinc, indium, lead, and bismuth. The sputter target may also include small amounts of nickel. For example, nickel may be included in the initial casting process. The sputter target may include a wetting layer, which may include any suitable material, including, for example, nickel. A sputter target may be machine-cast. For example, a thermal spray target may be machine-cast.

During the sputtering process, the distance between the target and the substrate can be great enough to reduce arcing. The sheet resistance of the sputtered film can be any suitable value. For example, the sheet resistance of the sputtered film can be more than about 100 Ohms/square, more than about 400 Ohms/square, more than about 1000 Ohms/square, less than about 3000 Ohms/square, or less than about 2000 Ohms/square. The transparent conductive oxide layer may have a sheet resistance of more than about 100 Ohms/square. The transparent conductive oxide layer may have a sheet resistance of less than about 1500 Ohms/square. The transparent conductive oxide layer may have a sheet resistance of about 200 to about 1000 Ohms/square. The transparent conductive oxide layer may have a sheet resistance of about 800 to about 1200 Ohms/square. The transparent conductive oxide layer may have a sheet resistance of about 100 to about 500 Ohms/square. The targets can be deposited using any suitable technique, including, for example, dual magnetron sputtering.

Like barrier layer 120, transparent conductive oxide layer 130 may be deposited at an enhanced rate by incorporating argon gas into the deposition environment. For example, transparent conductive oxide layer 130 may be deposited in the presence of an oxygen/argon gas mix. An argon content in barrier layer 120 and transparent conductive oxide layer 130 may be detectable following deposition. For example, barrier layer 120 or transparent conductive oxide layer 130 can either or both include argon in an amount of 1-10,000 ppm, for example, 10-1,000 ppm. Transparent conductive oxide layer 130 and the other layers can be formed at any suitable pressure. For example, transparent conductive oxide layer 130 can be deposited having a pressure of about 3 to about 8 millitorr, or about 5 millitorr.

Transparent conductive oxide layer 130 may include any suitable material, including, for example, an amorphous layer of cadmium stannate. Transparent conductive oxide layer 130 may have any suitable thickness, including, for example, more than about 2000 A, more than about 2500 A, or less than about 3000 A. For example, transparent conductive oxide layer 130 may have a thickness of about 2600 A.

A buffer layer 140 may be formed onto transparent conductive oxide layer 130. Buffer layer 140 can be deposited between the TCO layer and a semiconductor window layer to decrease the likelihood of irregularities occurring during the formation of the semiconductor window layer. Buffer layer 140 may include any suitable material, including, for example, an amorphous tin oxide. Buffer layer 140 can include any other suitable material, including zinc tin oxide, zinc oxide, and zinc magnesium oxide. Buffer layer 140 may have any suitable thickness, including, for example, more than about 500 A, more than about 650 A, more than about 800 A, or less than about 1200 A. For example, buffer layer 140 may have a thickness of about 900 A. Buffer layer 140 may be deposited using any suitable means, including, for example, sputtering. For example, buffer layer 140 may include a tin oxide sputtered in the presence of an oxygen gas. Buffer layer 140, along with barrier layer 120 and transparent conductive oxide layer 130, can form transparent conductive oxide stack 110.

The layers included in the structure and photovoltaic device can be created using any suitable technique or combination of techniques. For example, the layers can be formed by low pressure chemical vapor deposition, atmospheric pressure chemical vapor deposition, plasma-enhanced chemical vapor deposition, thermal chemical vapor deposition, DC or AC sputtering, spin-on deposition, and spray-pyrolysis. Each deposition layer can be of any suitable thickness, for example in the range of about 1 to about 5000 A.

The deposition rate of the TCO stack may be expedited by incorporating an argon gas into the deposition chamber, in addition to oxygen gas. For example, the barrier and/or TCO layer can be sputtered in the presence of an oxygen/argon gas mix to facilitate the deposition process. A silicon aluminum oxide can be deposited onto a glass substrate, which may include any suitable glass, including, for example, soda-lime glass or any glass with a reduced iron content. The glass may have one or more rounded edges to enable the substrate to withstand high anneal temperatures (e.g., about 600 degrees C.). The TCO layer may have a low roughness to facilitate smooth cadmium sulfide deposition, thereby resulting in greater control of the cadmium sulfide/cadmium telluride junction interface. The sheet resistance of the TCO layer may be controlled by monitoring the cell width. The TCO layer, which may include a cadmium tin oxide, for example, may be deposited on the silicon aluminum oxide, in the presence of an oxygen/argon gas mix. The incorporation of argon during the sputtering of the silicon aluminum oxide and the cadmium tin oxide can increase the deposition rate by a factor of about 2.

The barrier layer, transparent conductive oxide layer, and/or buffer layer can be formed by sputtering respective sputter targets including suitable sputter materials. For example, if the barrier layer includes silicon aluminum oxide (e.g., SiAlOₓ), the sputter target can include suitable amounts of silicon and aluminum. The sputter target can be sputtered in an oxygen-containing environment. For example, the target can have a silicon:aluminum ratio in the range of 95:5 to 65:35. The target can have a silicon:aluminum ratio in the range of 80:20 to 85:15. A sputter target for creating a cadmium stannate transparent conductive oxide layer can include cadmium and tin. A sputter target for forming a tin oxide buffer layer can include tin and can be sputtered in an oxygen-containing environment.

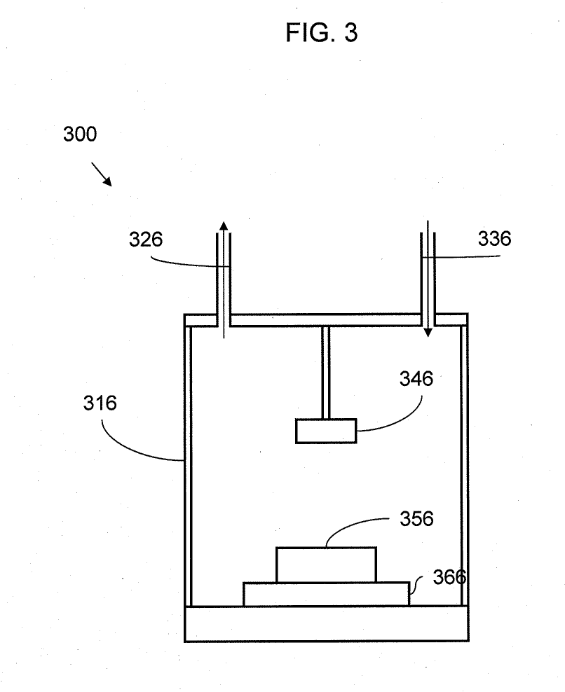

Referring to FIG. 3, a sputter system 300 may include a chamber 316 and a sputter target 346. Sputter target 346 may include any suitable material, including, for example, quantities of cadmium and tin. Substrate 356, which may include any suitable substrate material, including, for example, a glass, including, for example, a soda-lime glass, may be mounted on a plate 366 or positioned in any other suitable manner. Any suitable gas may be incorporated into chamber 316 via gas inlet 336, including, for example, argon, oxygen, or nitrogen, as well as any suitable dopant gas, including, for example, boron, sodium, fluorine, or aluminum.

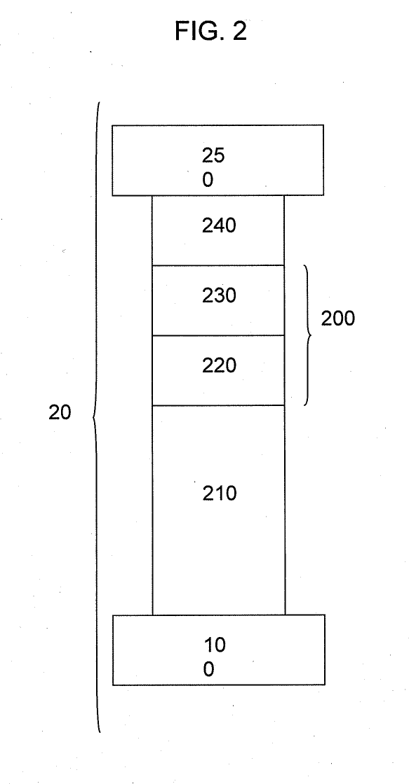

Following deposition, transparent conductive oxide stack 110 can be annealed to form annealed stack 210 from FIG. 2, which can lead to formation of cadmium stannate. Transparent conductive oxide stack 110 can be annealed using any suitable annealing process. The annealing can occur in the presence of a gas selected to control an aspect of the annealing, for example, nitrogen gas. Transparent conductive oxide stack 110 can be annealed under any suitable pressure, for example, under reduced pressure, in a low vacuum, or at about 0.01 Pa (10⁻⁴ Torr). Transparent conductive oxide stack 110 can be annealed at any suitable temperature or temperature range. For example, transparent conductive oxide stack 110 can be annealed above about 380 degrees C., above about 400 degrees C., above about 500 degrees C., above about 600 degrees C., or below about 800 degrees C. For example, transparent conductive oxide stack 110 can be annealed at about 400 degrees C. to about 800 degrees C. or about 500 degrees C. to about 700 degrees C. Transparent conductive oxide stack 110 can be annealed for any suitable duration. Transparent conductive oxide stack 110 can be annealed for more than about 10 minutes, more than about 20 minutes, more than about 30 minutes, or less than about 40 minutes. For example, transparent conductive oxide stack 110 can be annealed for about 15 to about 20 minutes. Following anneal, the transparent conductive oxide layer in annealed transparent conductive oxide stack 210 can have an altered sheet resistance. For example, following anneal, the transparent conductive oxide layer from annealed transparent conductive oxide stack can have a sheet resistance of more than about 5 Ohms/square, more than about 7 Ohms/square, more than about 10 Ohms/square, less than about 15 Ohms/square, less than about 12 Ohms/square, or less than about 8 Ohms/square. For example, annealed stack having a thickness of about 2000 A could have a sheet resistance of about 6 Ohms/square, and an annealed stack having a thickness of about 2500 A could have a sheet resistance of about 12 Ohms/square. Accordingly, the bulk resistance of the transparent conductive oxide layer after anneal can be more than about 1.0×10⁻⁴ Ohm cm, or less than about 3×10⁻⁴ Ohm cm.

Annealed transparent conductive oxide stack 210 can be used to form photovoltaic device 20 from FIG. 2. Referring to FIG. 2, a semiconductor layer 200 can be deposited onto annealed transparent conductive oxide stack 210. Semiconductor layer 200 can include a semiconductor window layer 220 and a semiconductor absorber layer 230. Semiconductor window layer 220 can be deposited directly onto annealed transparent conductive oxide stack 210. Semiconductor window layer 220 can be deposited using any known deposition technique, including vapor transport deposition. Semiconductor absorber layer 230 can be deposited onto semiconductor window layer 220. Semiconductor absorber layer 230 can be deposited using any known deposition technique, including vapor transport deposition. Semiconductor window layer 220 can include a cadmium sulfide layer. Semiconductor absorber layer 230 can include a cadmium telluride layer. A back contact 240 can be deposited onto semiconductor layer 200. Back contact 240 can be deposited onto semiconductor absorber layer 230. A back support 250 can be formed or positioned on back contact 240.

Photovoltaic cells fabricated using the methods discussed herein may be incorporated into one or more photovoltaic modules. For example, photovoltaic cells fabricated using the aforementioned methods may be incorporated into multiple submodules, which may be assembled into larger photovoltaic modules. Such modules may by incorporated into various systems for generating electricity. For example, a photovoltaic module may include one or more submodules consisting of multiple photovoltaic cells connected in series. One or more submodules may be connected in parallel via a shared cell to form a photovoltaic module.

A bus bar assembly may be attached to a contact surface of a photovoltaic module to enable connection to additional electrical components (e.g., one or more additional modules). For example, a first strip of double-sided tape may be distributed along a length of the module, and a first lead foil may be applied adjacent thereto. A second strip of double-sided tape (smaller than the first strip) may be applied adjacent to the first lead foil. A second lead foil may be applied adjacent to the second strip of double-sided tape. The tape and lead foils may be positioned such that at least one portion of the first lead foil is exposed, and at least one portion of the second lead foil is exposed. Following application of the tape and lead foils, a plurality of bus bars may be positioned along the contact region of the module. The bus bars may be positioned parallel from one another, at any suitable distance apart. For example, the plurality of bus bars may include at least one bus bar positioned on a portion of the first lead foil, and at least one bus bar positioned on a portion of the second lead foil. The bus bar, along with the portion of lead foil on which it has been applied, may define a positive or negative region. A roller may be used to create a loop in a section of the first or second lead foil. The loop may be threaded through the hole of a subsequently deposited back glass. The photovoltaic module may be connected to other electronic components, including, for example, one or more additional photovoltaic modules. For example, the photovoltaic module may be electrically connected to one or more additional photovoltaic modules to form a photovoltaic array.

The photovoltaic cells/modules/arrays may be included in a system for generating electricity. For example, a photovoltaic cell may be illuminated with a beam of light to generate a photocurrent. The photocurrent may be collected and converted from direct current (DC) to alternating current (AC) and distributed to a power grid. Light of any suitable wavelength may be directed at the cell to produce the photocurrent, including, for example, more than 400 nm, or less than 700 nm (e.g., ultraviolet light). Photocurrent generated from one photovoltaic cell may be combined with photocurrent generated from other photovoltaic cells. For example, the photovoltaic cells may be part of one or more photovoltaic modules in a photovoltaic array, from which the aggregate current may be harnessed and distributed.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

1-15. (canceled)

16. A multilayered structure comprising:
a substrate;
a barrier layer comprising silicon aluminum oxide adjacent to the substrate;
a transparent conductive oxide layer comprising cadmium stannate adjacent to the barrier layer; and
a buffer layer comprising tin oxide adjacent to the transparent conductive oxide layer.

17. The structure of claim 16, wherein the transparent conductive oxide layer further comprises a material selected from the group consisting of nickel, zinc, indium, lead, and bismuth.

18. The structure of claim 16, wherein the transparent conductive oxide layer further comprises more than about 0.001 wt. % nickel.

19. The structure of claim 16, wherein the transparent conductive oxide layer further comprises less than about 1.0 wt. % nickel.

20. The structure of claim 16, wherein the transparent conductive oxide layer has a sheet resistance of more than about 100 Ohms/square.

21. The structure of claim 16, wherein the transparent conductive oxide layer has a sheet resistance of less than about 1500 Ohms/square.

22. The structure of claim 16, wherein the transparent conductive oxide layer comprises an annealed layer having a sheet resistance of more than about 5 Ohms/square.

23. The structure of claim 16, wherein the transparent conductive oxide layer comprises an annealed layer having a sheet resistance of less than about 15 Ohms/square.

24. A photovoltaic device comprising:
a substrate;
a barrier layer comprising silicon aluminum oxide adjacent to the substrate;
a transparent conductive oxide layer comprising cadmium stannate adjacent to the barrier layer;
a buffer layer comprising tin oxide adjacent to the transparent conductive oxide layer;
a semiconductor window layer adjacent to the buffer layer;
a semiconductor absorber layer adjacent to the semiconductor window layer; and
a back contact adjacent to the semiconductor absorber layer.

25. The photovoltaic device of claim 24, wherein the transparent conductive oxide layer further comprises a material selected from the group consisting of nickel, zinc, indium, lead, and bismuth.

26. The photovoltaic device of claim 24, wherein the transparent conductive oxide layer further comprises more than about 0.001 wt. % nickel.

27. The photovoltaic device of claim 24, wherein the transparent conductive oxide layer further comprises less than about 1.0 wt. % nickel.

28. The photovoltaic device of claim 24, wherein the transparent conductive oxide layer has a sheet resistance of more than about 100 Ohms/square.

29. The photovoltaic device of claim 24, wherein the transparent conductive oxide layer has a sheet resistance of less than about 1500 Ohms/square.

30. The photovoltaic device of claim 24, wherein the transparent conductive oxide layer comprises an annealed layer having a sheet resistance of more than about 5 Ohms/square.

31. The photovoltaic device of claim 24, wherein the transparent conductive oxide layer comprises an annealed layer having a sheet resistance of less than about 15 Ohms/square.

32. The photovoltaic device of claim 24, further comprising a back support adjacent to the back contact.

33. The photovoltaic device of claim 24, wherein the semiconductor window layer comprises cadmium sulfide and the semiconductor absorber layer comprises cadmium telluride.

34. A photovoltaic module comprising:
a plurality of photovoltaic cells adjacent to a substrate; and
a back cover adjacent to the plurality of photovoltaic cells, each one of the plurality of photovoltaic cells comprising:
a barrier layer comprising silicon aluminum oxide adjacent to the substrate;
a transparent conductive oxide layer comprising cadmium stannate adjacent to the barrier layer;
a buffer layer comprising tin oxide adjacent to the transparent conductive oxide layer;
a semiconductor window layer adjacent to the buffer layer;
a semiconductor absorber layer adjacent to the semiconductor window layer; and
a back contact adjacent to the semiconductor absorber layer.

35. The photovoltaic module of claim 34, further comprising:
a first strip of tape having a length distributed along the back contacts, the first strip of tape comprising a front surface and a back surface, each surface containing an adhesive;
a first lead foil distributed along the length of the first strip of tape;
a second strip of tape, having a length shorter than that of the first strip of tape, distributed along the length and between the ends of the first strip of tape, wherein the second strip of tape comprises a front and back surface, each containing an adhesive;
a second lead foil, having a length shorter than that of the second strip of tape, distributed along the length of the second strip of tape; and
a plurality of parallel bus bars, positioned adjacent and perpendicular to the first and second strips of tape, wherein each one of the plurality of parallel bus bars contacts one of the first or second lead foils.

36. The photovoltaic module of claim 34, further comprising first and second submodules, wherein the first submodule comprises two or more cells of the plurality of photovoltaic cells connected in series, and the second submodule comprises another two or more cells of the plurality of photovoltaic cells connected in series, wherein the first and second submodules are connected in parallel through a shared cell.

37. A method for generating electricity, the method comprising:
illuminating a photovoltaic cell with a beam of light to generate a photocurrent; and
collecting the generated photocurrent, wherein the photovoltaic cell comprises:
a substrate;
a barrier layer comprising silicon aluminum oxide adjacent to the substrate;
a transparent conductive oxide layer comprising cadmium stannate adjacent to the barrier layer;
a buffer layer comprising tin oxide adjacent to the transparent conductive oxide layer;
a semiconductor window layer adjacent to the buffer layer;
a semiconductor absorber layer adjacent to the semiconductor window layer; and
a back contact adjacent to the semiconductor absorber layer.

38. The method of claim 37, wherein the beam of light comprises a wavelength of more than about 400 nm.

39. The method of claim 37, wherein the beam of light comprises a wavelength of less than about 700 nm.

40. The method of claim 37, wherein the beam of light comprises ultraviolet light.

41. The method of claim 37, wherein the beam of light comprises blue light.

42. The method of claim 37, wherein the beam of light comprises white light.

43. The method of claim 37, further comprising converting the photocurrent from DC to AC.
